(19) United States
(12) Patent Application Publication
(10) Pub. No.: US 2025/0372441 A1
(43) Pub. Date: Dec. 4, 2025

(54) SEMICONDUCTOR DEVICE AND MANUFACTURING METHOD THEREOF

(71) Applicant: NANYA TECHNOLOGY CORPORATION, New Taipei City (TW)

(72) Inventor: Ying Chou LU, New Taipei City (TW)

(21) Appl. No.: 18/675,166

(22) Filed: May 28, 2024

(51) Int. Cl. H01L 21/762; H01L 21/3065

(52) U.S. Cl. CPC H01L 21/76224; H01L 21/3065

(57) ABSTRACT

A manufacturing method of a semiconductor device includes performing a pulsing etching process to a substrate to form a trench in a substrate, in which the pulsing etching process includes a plurality of cycles, each of the cycles includes an etching period and a passivation period, and a source power of the passivation period is higher than a source power of the etching period, and forming an isolation structure in the trench.

### BACKGROUND

### Field of Disclosure

The present disclosure relates to a semiconductor device and a manufacturing method thereof.

### Description of Related Art

Isolation structures, such as shallow trench isolation (STI), are an integrated circuit feature which prevents electric current leakage between adjacent semiconductor device components. Generally, the isolation structures are formed by etching a semiconductor substrate to form trenches in the semiconductor substrate, and then filling dielectric materials in the trenches of the semiconductor substrate. During etching the semiconductor substrate, the profiles of the trenches may be wiggling, which cause the profiles of protrusion portions of the semiconductor substrate wiggling. The wiggling issue of the protrusion portions of the semiconductor substrate may cause some problems in the final product.

### SUMMARY

Some embodiments of the present disclosure provides a manufacturing method of a semiconductor device including performing a pulsing etching process to a substrate to form a trench in a substrate, in which the pulsing etching process includes a plurality of cycles, each of the cycles includes an etching period and a passivation period, and a source power of the passivation period is higher than a source power of the etching period, and forming an isolation structure in the trench.

Some embodiments of the present disclosure, a bias power of the passivation period is lower than a bias power of the etching period.

Some embodiments of the present disclosure, a bias power of the passivation period is zero.

Some embodiments of the present disclosure, a bias power of the etching period is between 1100 and 1300 W.

Some embodiments of the present disclosure, a duration of the etching period accounts for 15%-30% of a duration of each of the cycles.

Some embodiments of the present disclosure, the source power of the passivation period is between 850 W and 1050 W.

Some embodiments of the present disclosure, the source power of the passivation period is 250 W-800 W higher than the source power of the etching period.

Some embodiments of the present disclosure, the source power of the passivation period is 250 W-650 W higher than the source power of the etching period.

Some embodiments of the present disclosure, a process gas used in the etching period and a process gas used in the passivation period is the same.

Some embodiments of the present disclosure, the pulsing etching process includes a first cycle, and performing the pulsing etching process includes introducing a process gas to recess the substrate during the etching period of the first cycle, and using the process gas to oxidize a sidewall of the recess during the passivation period of the first cycle.

Some embodiments of the present disclosure, the process gas etches the substrate faster than oxidizes a surface of the substrate during the etching period of the first cycle.

Some embodiments of the present disclosure, the process gas oxidizes the substrate faster than etches the substrate during the passivation period of the first cycle.

Some embodiments of the present disclosure, a bottom of the recess is oxidized during the passivation period of the first cycle.

Some embodiments of the present disclosure, the pulsing etching process further includes a second cycle after the first cycle, and performing the pulsing etching process further includes etching a passivation layer at the bottom of the recess after the bottom of the recess is oxidized during the etching period of the second cycle.

Some embodiments of the present disclosure, the process gas etches the passivation layer at the bottom of the recess faster than etches the passivation layer at the sidewall of the recess during the etching period of the second cycle.

Some embodiments of the present disclosure, the process gas etches the substrate faster than etches the passivation layer at the sidewall of the recess during the etching period of the second cycle.

Some embodiments of the present disclosure, a process gas used in the pulsing etching process is a combination of chlorine, oxygen, helium.

Some embodiments of the present disclosure, the manufacturing method further includes forming a hard mask layer over the substrate before forming the trench in the substrate, in which the trench is formed by etching the substrate through the hard mask layer.

Some embodiments of the present disclosure, forming the isolation structure in the trench includes forming a dielectric layer overfilling the trench, and performing a planarization process to remove an excess portion of the dielectric layer.

Some embodiments of the present disclosure, a top surface of the isolation structure is level with a top surface of the substrate.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates an etching apparatus 10 used in some embodiments of the present disclosure.

FIGS. 2-8 illustrate a method of manufacturing a semiconductor device in some embodiments.

FIG. 9 illustrates a scanning electron microscope (SEM) image of the semiconductor device in some embodiments of the present disclosure.

FIGS. 10A-10F illustrates cross-section views at different depths of the semiconductor device in FIG. 9.

### DETAILED DESCRIPTION

Some embodiments of the present disclosure provide a method of forming isolation structures and active regions in a substrate. The method includes performing a pulsing etching process to form trenches in the substrate. A dielectric material is subsequently filled in the trenches to form the isolation structures. The pulsing etching process is used to improve the wiggling issue of the active regions. The wiggling issue of the active regions may cause the voids after the isolation structures are formed in the trenches, thereby causing the current leakage and affecting the device performance.

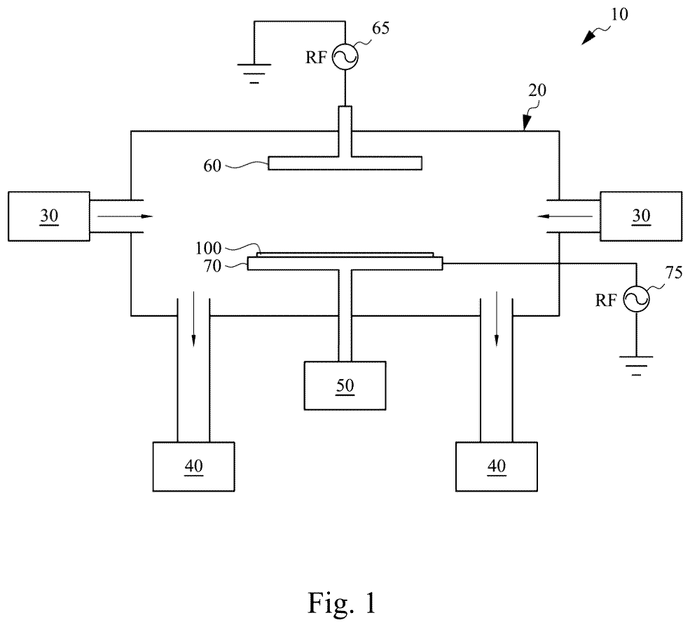

FIG. 1 illustrates an etching apparatus 10 used in some embodiments of the present disclosure. The etching apparatus 10 may be a plasma process system, and may include a chamber 20, a gas supply system 30, a gas exhaust system 40, a temperature controller 50, an electrode 60, a holder 70 and radio frequency powers 65 and 75.

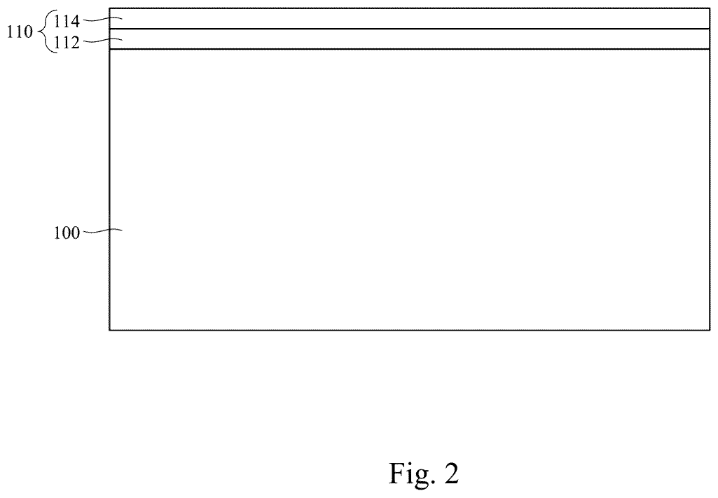

The holder 70 is placed in the chamber 20 and used to hold a substrate 100 during an etching process. The etching process is used to form trenches in the substrate 100 in FIGS. 2-8 in later discussion. The gas supply system 30 and the gas exhaust system 40 are connected with the chamber 20 to transport process gas into and out from the chamber 20 respectively. The electrode 60 is over the holder 70. The electrode 60 and the holder 70 are coupled to the radio frequency powers 65 and 75 respectively. The radio frequency power 65 is used to adjusting source power, and the radio frequency power 65 is used to adjusting bias power during the etching process.

Specifically, during the process of forming the trenches in the substrate 100, the process gas transported into the chamber 20 by the gas supply system 30 is ionized between the electrode 60 coupled to the radio frequency power 65 and the holder 70 coupled to the radio frequency power 75. The ionized process gas is used to form the trenches in the substrate 100. Adjusting the value of the radio frequency power 65 may adjusting the amount of the ionized process gas. Adjusting the value of the of the radio frequency power 75 may adjusting the directionality of ionized process gas. The higher the value of the radio frequency power 65, the greater amount of ionized process gas. The higher the value of the radio frequency power 75, the higher directionality of ionized process gas towards the substrate 100.

FIGS. 2-8 illustrate a method of manufacturing a semiconductor device in some embodiments. Referring to FIG. 2, a substrate 100 is provided in the chamber 20 in FIG. 1. Specifically, the substrate 100 is placed at the holder 70 in FIG. 1, and the upper surface of the substrate 100 faces the electrode 60. The substrate 100 may be a semiconductor substrate. In some embodiments, the substrate 100 may be made of silicon, germanium, SiGe, GaAs, InSb, GaP, GaSb, InAlAs, InGaAs, GaSbP, GaAsSb or InP.

Subsequently, a hard mask layer 110 is formed over the substrate 100. The hard mask layer 110 may include one or more dielectric layers. In some embodiments, the hard mask layer 110 may include a first hard mask layer 112 and a second hard mask layer 114 over the first hard mask layer 112, and the first hard mask layer 112 and the second hard mask layer 114 may be formed by different material. For example, the first hard mask layer 112 may be made of silicon oxide, and the second hard mask layer 114 may be made of silicon nitride.

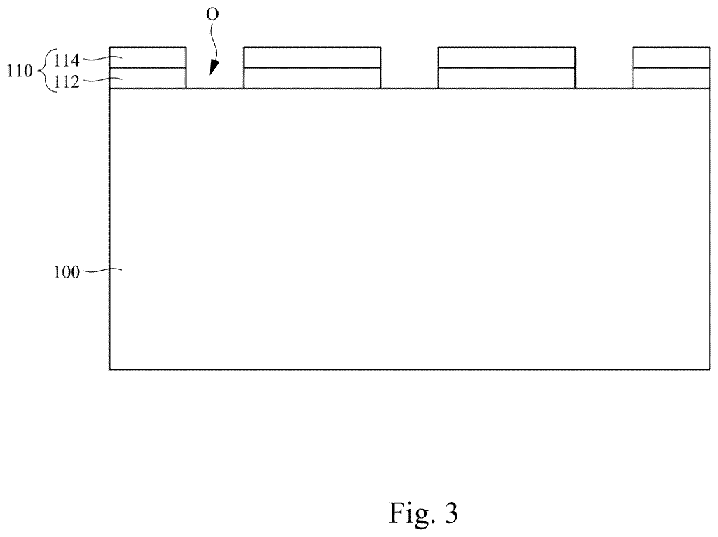

Referring to FIG. 3, the hard mask layer 110 is patterned to form openings O in the hard mask layer 110, and thus the openings O expose the substrate 100 below.

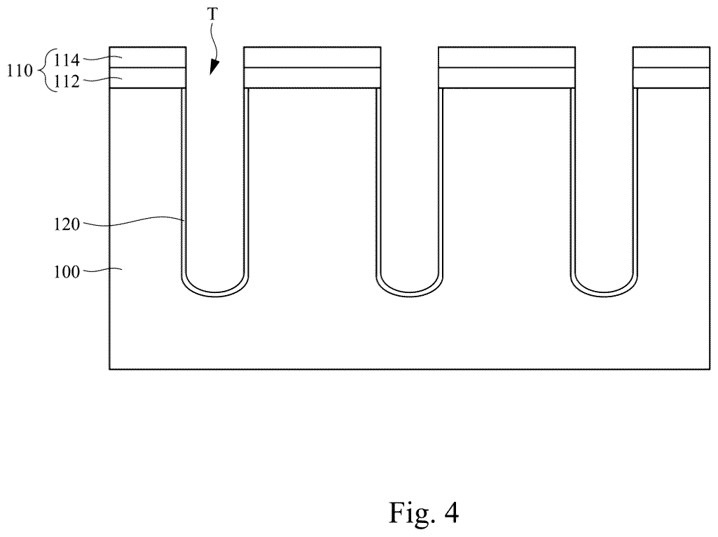

Referring to FIG. 4, a pulsing etching process is performed to the substrate 100 to form trenches T in a substrate 100. The trenches T are used for accommodating isolation structures in the subsequent process, and protrusion portions of the substrate 100 may serve as active regions in the final product. The trenches T are formed by etching the substrate 100 through the hard mask layer 110. The pulsing etching process may be used to provide protection at the sidewalls of the trenches T. Specifically, during the pulsing etching process, passivation layers 120 are naturally formed lining the trenches T. The passivation layers 120 are used to prevent the trenches T from being over-etched laterally. Therefore, the width of the respective trench T remains substantially the same throughout the entire trench T. The width of the respective protrusion portion of the substrate 100 also remains substantially the same throughout the entire protrusion portion of the substrate 100. That is, the wiggling issue of the protrusion portion of the substrate 100 is improved. In some embodiments, the passivation layers 120 are made of silicon oxide.

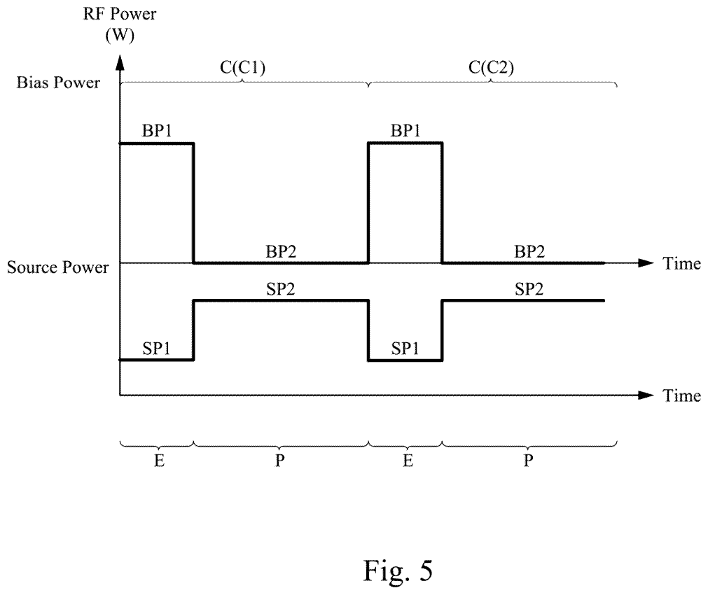

FIG. 5 illustrates a recipe of the pulsing etching process in some embodiments of the present disclosure. Referring to FIG. 5, the pulsing etching process includes a plurality of cycles C, such as a first cycle C1 and a second cycle C2, and each of the cycles C includes an etching period E and a passivation period P. A process gas is introduced to the substrate 100 in FIG. 4 to form the trench T in FIG. 4, and the bias power and the source power of the etching period E and the passivation period P are adjusted to form the passivation layer 120 in FIG. 4 lining the trench T in FIG. 4. In some embodiments, a process gas used in the pulsing etching process is a combination of chlorine, oxygen, helium. As a result, the speed of etching the substrate 100 and the speed of forming the passivation layer may be different between etching period E and the passivation period P. In the present disclosure, the process gas etches the substrate 100 faster than oxidizes a surface of the substrate 100 during the etching period E, and the process gas oxidizes the substrate 100 faster than etches the substrate 100 during the passivation period P.

A first cycle C1 of the pulsing etching process is performed. The first cycle C1 starts with an etching period E. During the etching period E, a first source power SP1 (i.e. the radio frequency power 65 in FIG. 1 is adjusted to the first source power SP1) is applied to the electrode 60 in FIG. 1 over the substrate 100, and a first bias power BP1 (ie. the radio frequency power 75 in FIG. 1 is adjusted to the first bias power BP1) is applied to the holder 70 under the substrate 100. The process gas is ionized to etch the substrate 100. In some embodiments, the first bias power BP1 of the etching period E is between 1100 and 1300 W. If the first bias power BP1 is below the range disclosed above, the directionality of the ionized process gas is not enough to provide enough etching ability. In some embodiments, the first source power SP1 of the etching period E is between 350 and 500 W.

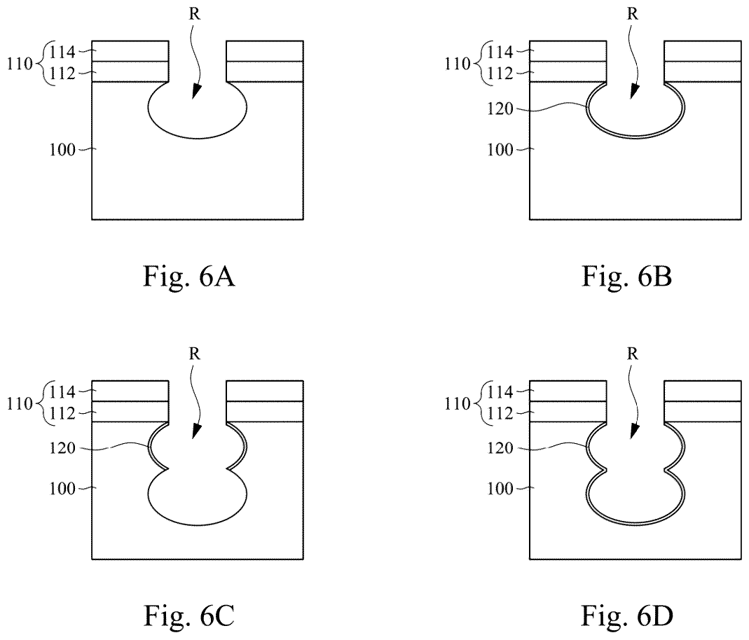

FIGS. 6A-6D illustrate steps of the pulsing etching process in some embodiments of the present disclosure. Referring to FIGS. 5 and 6A, the process gas is introduced to recess the substrate 100 through the hard mask layer 110 during the etching period E in FIG. 5. The process gas may recess the substrate 100 vertically. Specifically, during the etching period E, the first bias power BP1 is high, and thus the directionality of the etching process of the substrate 100 is high. Stated another way, the ionized process gas moves toward the substrate 100 with a high directionality during the etching period E, and thus the ionized process gas has a high etching ability.

Next, back to FIG. 5, the etching period E is followed by a passivation period P in the first cycle C1. During the passivation period P, a second source power SP2 is applied to the electrode (not illustrated) over the substrate 100, and a second bias power BP2 is applied to a holder (not illustrated) under the substrate 100. The second bias power BP2 of the passivation period P is lower than the first bias power BP1 of the etching period E. In some embodiments, the second bias power BP2 of the etching period is 0 W. The second source power SP2 of the passivation period P is higher than the first source power SP1 of the etching period E. In some embodiments, the second source power SP2 of the passivation period P is between 850 W and 1050 W. In some embodiments, the second source power SP2 of the passivation period P is 250 W-800 W higher than the first source power SP1 of the etching period E. In some embodiments, the second source power SP2 of the passivation period P is 250 W-650 W higher than the first source power SP1 of the etching period E. If the second source power SP2 is below the range disclosed above, the amount of the ionized process gas may be not enough to oxidize the surface of the substrate 100 to form the passivation layer 120, or the surface of the substrate 100. If the second source power SP2 is beyond the range disclosed above, the surface of the substrate 100 may be oxidized too much to stop the etching while forming the trenches, or the difference between the sizes of the trenches may increases due to microloading effect. In some embodiments, the flow rate of the process gas during the etching period E and the passivation period P are the same. Therefore, the amount of the ionized process gas is only determined by the value of the source power.

Referring to FIGS. 5 and 6B, the process gas oxidizes a sidewall of the recess R during the passivation period P of the first cycle C1. Specifically, the process gas using in the passivation period P and the process gas using in the etching period E are the same, and the process gas includes oxygen. The oxygen oxidizes the sidewall of the recess R to convert the surface of the substrate 100 into a passivation layer 120. Specifically, the second bias power BP2 of the passivation period P is lower than the first bias power BP1 of the etching period E, and the second source power SP2 of the passivation period P is higher than the first source power SP1 of the etching period E. Therefore, the amount of the ionized process gas during the passivation period P is greater than the amount of the ionized process gas during the etching period E, and the directionality of the ionized process gas during the etching period E is lower than the directionality of the ionized process gas during the passivation period P. Stated another way, the substrate 100 is exposed in the environment containing ionized process gas with weak etching ability. Since the amount of the ionized process gas during the passivation period P is greater than the amount of the ionized process gas during the etching period E, the amount of the ionized process gas is able to oxidize the sidewall of the recess R to convert the surface of the substrate 100 into a passivation layer 120. In some embodiments where the substrate 100 is made of silicon, the passivation layer 120 is made of silicon oxide. The passivation layer 120 prevents the substrate 100 from being over-etched laterally. In some embodiments, a bottom of the recess R is oxidized during the passivation period P.

Back to FIG. 5, a duty cycle of the first cycle C1 may be adjusted. The term “duty cycle” is defined as a proportion of the duration of the etching period E accounting for the duration of the cycle. The duration of the etching period E is shorter than the duration of the passivation period P, so the passivation layers 120 are able to be formed lining the trenches T in FIG. 4. In some embodiments, the duration of the etching period E accounts for 15%-30% of a duration of the first cycle C1. If the duration of the etching period E is below the range disclosed above, the surface of the substrate 100 in FIG. 4 may be oxidized too much to stop the etching while forming the trenches T. If the duration of the etching period E is beyond the range disclosed above, the passivation layers 120 may not be thick enough to protect the sidewall of the trenches in FIG. 4, thereby causing wiggling issue of the trenches T due to the lateral etching of the trenches T.

Next, a second cycle C2 is performed after the first cycle C1 is finished. The process of the second cycle C2 and the first cycle C1 may be the same. That is, the first source power SP1 of the etching period E of the second cycle C2 may be same as the first source power SP1 of the etching period E of the first cycle C1. The first bias power BP1 of the etching period E of the second cycle C2 may be same as the first bias power BP1 of the etching period E of the first cycle C1.

Referring to FIGS. 5 and 6C, the substrate 100 is further recessed during the etching period E of the second cycle C2. The process gas etches the passivation layer 120 at the bottom of the recess R faster than etches the passivation layer 120 at the sidewall of the recess R, and the process gas etches the substrate 100 faster than etches the passivation layer 120 at the sidewall of the recess R. Therefore, during the etching period E of the second cycle C2 in FIG. 60, the passivation layer 120 at the sidewall of the recess R prevents a portion of the substrate 100 covered by the passivation layer 120 from being over-etched laterally.

Next, back to FIG. 5, the etching period E is followed by a passivation period P in the second cycle C2. The process of the second cycle C2 and the first cycle C1 may be the same. That is, the second source power SP2 of the passivation period P of the second cycle C2 may be same as the second source power SP2 of the passivation period P of the first cycle C1. The second bias power BP2 of the passivation period P of the second cycle C2 may be same as the second bias power BP2 of the passivation period P of the first cycle C1. The duty cycle of the second cycle C2 may be the same as the duty cycle of the first cycle C1.

Referring to FIGS. 5 and 6D, the passivation layer 120 is further formed lining the exposed substrate 100 during the passivation period P of the second cycle C2. The process of the passivation period P of the second cycle C2 is same as the process of the passivation period P of the first cycle C1. Therefore, related details are not described herein repeatedly. After the second cycle C2 is finished, the processes in FIGS. 6C and 6D are repeated until the depth of the recess R reaches a predetermined value. The resulting recess R becomes the trench T in FIG. 4.

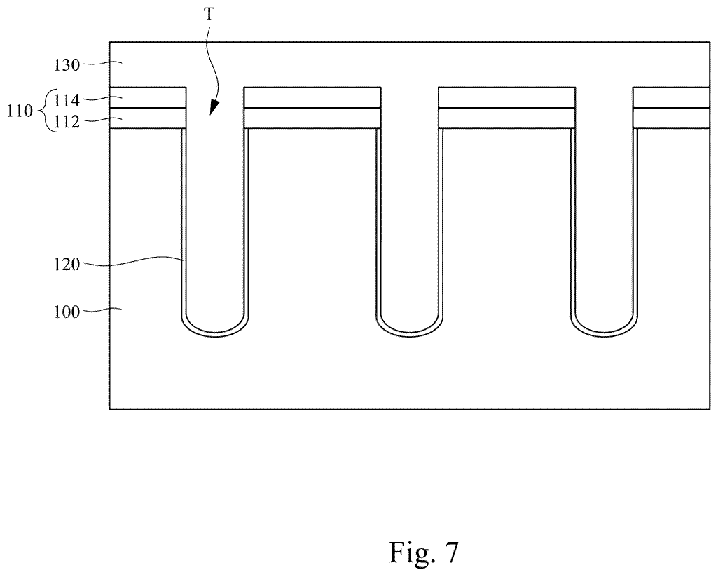

Referring to FIG. 7, a dielectric layer 130 is formed overfilling the trenches T and covering the hard mask layer 110. In some embodiments, the dielectric layer 130 is made of silicon oxide.

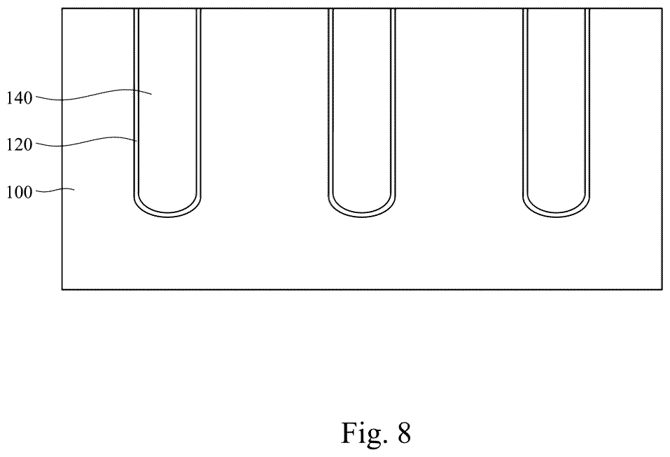

Referring to FIG. 8, an excess portion of the dielectric layer 130 is removed to form the isolation structures 140 in the trenches T. In some embodiments, the isolation structures 140 is formed by performing a planarization process to remove an excess portion of the dielectric layer 130 and the hard mask layer 110 until the top surface of the substrate 100 is exposed. In some other embodiments, the isolation structures 140 is formed by performing a planarization process to remove an excess portion of the dielectric layer 130 until the top surface of the hard mask layer 110 is exposed, and then the hard mask layer 110 and the dielectric layer 130 protruding from the substrate 100 are removed by an etching process. In some embodiments, the top surfaces of the isolation structures 140 are level with the top surface of the substrate 100. In some other embodiments, the top surfaces of the isolation structures 140 are slightly higher than the top surface of the substrate 100.

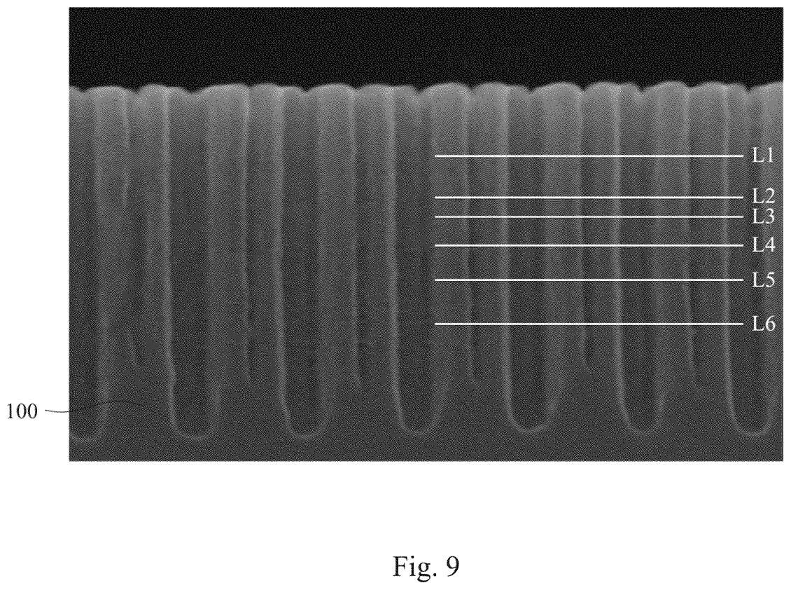

FIG. 9 illustrates a scanning electron microscope (SEM) image of the semiconductor device in some embodiments of the present disclosure. Since the substrate 100 is etched by performing a pulsing etching process, the width of the trench T remains substantially, and thus the width of the protrusion portion of the substrate 100 also remains substantially. Therefore, the wiggling issue of the protrusion portion of the substrate 100 is reduced.

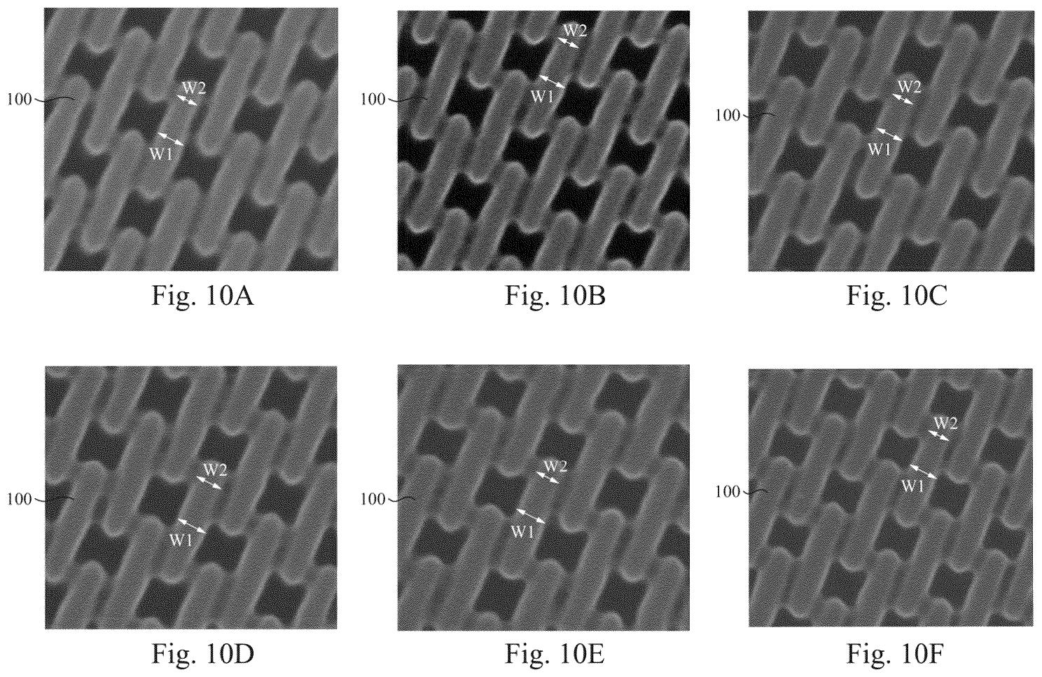

FIGS. 10A-10F illustrates cross-section views at different depths of the semiconductor device in FIG. 9. Specifically, FIG. 10A illustrates a cross-section view taken along L1 of the semiconductor device in FIG. 9. FIG. 10B illustrates a cross-section view taken along L2 of the semiconductor device in FIG. 9. FIG. 10C illustrates a cross-section view taken along L3 of the semiconductor device in FIG. 9. FIG. 10D illustrates a cross-section view taken along L4 of the semiconductor device in FIG. 9. FIG. 10E illustrates a cross-section view taken along L5 of the semiconductor device in FIG. 9. FIG. 10F illustrates a cross-section view taken along L6 of the semiconductor device in FIG. 9. Referring to FIGS. 10A-10F, the wiggling issue of the protrusion portion of the substrate 100 is also improved from the top view. Specifically, the maximum width W1 of the protrusion portion of the substrate 100 substantially remains the same in FIGS. 10A-10F, and the tip width W2 of the protrusion portion of the substrate 100 substantially remains the same in FIGS. 10A-10F. In some embodiments, the tip width W2 is more than 80% of the maximum width W1 in each of the FIGS. 10A-10F. In some embodiments, the error of the maximum width W1 is less than 15% throughout the protrusion portion of the substrate 100, and the error of the tip width W2 is less than 15% throughout the protrusion portion of the substrate 100 if the second source power of the passivation period is 250 W-800 W higher than the first source power of the etching period E in FIG. 5. In some embodiments, the error of the maximum width W1 is less than 10% throughout the protrusion portion of the substrate 100, and the error of the tip width W2 is less than 10% throughout the protrusion portion of the substrate 100 if the second source power of the passivation period is 250 W-650 W higher than the first source power of the etching period E in FIG. 5.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manufacturing method of a semiconductor device, comprising:
performing a pulsing etching process to a substrate to form a trench in the substrate, wherein the pulsing etching process comprises a plurality of cycles, each of the cycles comprises an etching period and a passivation period, and a source power of the passivation period is higher than a source power of the etching period; and
forming an isolation structure in the trench.

2. The manufacturing method of claim 1, wherein a bias power of the passivation period is lower than a bias power of the etching period.

3. The manufacturing method of claim 2, wherein a bias power of the passivation period is zero.

4. The manufacturing method of claim 1, wherein a bias power of the etching period is between 1100 and 1300 W.

5. The manufacturing method of claim 1, wherein a duration of the etching period accounts for 15%-30% of a duration of each of the cycles.

6. The manufacturing method of claim 1, wherein the source power of the passivation period is between 850 W and 1050 W.

7. The manufacturing method of claim 6, wherein the source power of the passivation period is 250 W-800 W higher than the source power of the etching period.

8. The manufacturing method of claim 7, wherein the source power of the passivation period is 250 W-650 W higher than the source power of the etching period.

9. The manufacturing method of claim 1, wherein a process gas used in the etching period and a process gas used in the passivation period is the same.

10. The manufacturing method of claim 1, wherein the pulsing etching process comprises a first cycle, and performing the pulsing etching process comprises:
introducing a process gas to recess the substrate during the etching period of the first cycle; and
using the process gas to oxidize a sidewall of the recess during the passivation period of the first cycle.

11. The manufacturing method of claim 10, wherein the process gas etches the substrate faster than oxidizes a surface of the substrate during the etching period of the first cycle.

12. The manufacturing method of claim 10, wherein the process gas oxidizes the substrate faster than etches the substrate during the passivation period of the first cycle.

13. The manufacturing method of claim 10, wherein a bottom of the recess is oxidized during the passivation period of the first cycle.

14. The manufacturing method of claim 13, wherein the pulsing etching process further comprises a second cycle after the first cycle, and performing the pulsing etching process further comprises:
etching a passivation layer at the bottom of the recess after the bottom of the recess is oxidized during the etching period of the second cycle.

15. The manufacturing method of claim 14, wherein the process gas etches the passivation layer at the bottom of the recess faster than etches the passivation layer at the sidewall of the recess during the etching period of the second cycle.

16. The manufacturing method of claim 14, wherein the process gas etches the substrate faster than etches the passivation layer at the sidewall of the recess during the etching period of the second cycle.

17. The manufacturing method of claim 1, wherein a process gas used in the pulsing etching process is a combination of chlorine, oxygen, helium.

18. The manufacturing method of claim 1, further comprising:
forming a hard mask layer over the substrate before forming the trench in the substrate, wherein the trench is formed by etching the substrate through the hard mask layer.

19. The manufacturing method of claim 18, wherein forming the isolation structure in the trench comprises:
forming a dielectric layer overfilling the trench; and
performing a planarization process to remove an excess portion of the dielectric layer.

20. The manufacturing method of claim 19, wherein a top surface of the isolation structure is level with a top surface of the substrate.
